(19) United States
(12) Patent Application Publication
(10) Pub. No.: US 2026/0262386 A1
(43) Pub. Date: Sep. 3, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Jun YAN, Beijing (CN); Xiangdan DONG, Beijing (CN); Wei ZHANG, Beijing (CN); Cong FAN, Beijing (CN); Yi HE, Beijing (CN); Yao HUANG, Beijing (CN); Kemeng TONG, Beijing (CN); Tao HAN, Beijing (CN); Zhiliang JIANG, Beijing (CN); Haijun QIU, Beijing (CN); Ming HU, Beijing (CN); Yongliang ZHAO, Beijing (CN); Yi ZHANG, Beijing (CN); Rui WANG, Beijing (CN); Taofeng XIE, Beijing (CN); Hai ZHENG, Beijing (CN); Fengli JI, Beijing (CN); Ansu LEE, Beijing (CN); Xueguang HAO, Beijing (CN); Hongli WANG, Beijing (CN); Yong QIAO, Beijing (CN); Kening ZHENG, Beijing (CN); Langtao LI, Beijing (CN)

(21) Appl. No.: 18/866,019

(22) PCT Filed: Aug. 12, 2024
(86) PCT No.: PCT/CN2024/111453

§ 371 Date: Nov. 14, 2024

(30) Foreign Application Priority Data
Sep. 28, 2023 (CN) 202311284921.0

(51) Int. Cl. H10K 59/122; H10K 59/12; H10K 59/124; H10K 59/80; H10K 102/00

(52) U.S. Cl. CPC H10K 59/122; H10K 59/1201; H10K 59/124; H10K 59/80521; H10K 59/8723; H10K 2102/351

(57) ABSTRACT

Provided is display panel. The display panel has a display region, an aperture region, and a peripheral region, the peripheral region being disposed around the aperture region, and the display region surrounding the peripheral region; wherein the display panel comprises: a substrate, disposed within the display region and the peripheral region; an inorganic insulating layer, disposed on a side of the substrate, and extending from the display region to the peripheral region; a plurality of conductive isolation pillars; an insulative isolation layer; an organic material layer; and a first electrode, disposed on a side, away from the substrate, of the organic material layer and extending from the display region to the peripheral region.

### CROSS-REFERENCE TO RELATED APPLICATION

This application is a U.S. national phase application based on PCT/CN2024/111453, filed on Aug. 12, 2024, which claims priority to Chinese patent Application No. 202311284921.0, filed on Sep. 28, 2023, the contents of which are incorporated herein by reference in their entireties.

### TECHNICAL FIELD

The present disclosure related the field of display technologies, and in particular, relates to a display panel and a display device.

### BACKGROUND

Organic light-emitting diodes (OLEDs), as display products of a new generation, have the advantages of rich colors, fast response, foldability, and the like. Nowadays, the OLEDs are gradually becoming the mainstream medium and small-sized display products in place of liquid crystal display (LCD) products. With further development of the OLEDs, higher requirements are imposed on the OLEDs, such as long life time, low power consumption, and support for high brightness mode.

### SUMMARY

Embodiments of the present disclosure provide a display panel and a display device.

The embodiments of the present disclosure provide a display panel. The display panel has a display region, an aperture region, and a peripheral region, the peripheral region being disposed around the aperture region, and the display region surrounding the peripheral region, and the display panel includes:
a substrate, disposed within the display region and the peripheral region;
an inorganic insulating layer, disposed on a side of the substrate, and extending from the display region to the peripheral region;
a plurality of conductive isolation pillars, disposed on a side, away from the substrate, of the inorganic insulating layer and disposed within the peripheral region, wherein the plurality of conductive isolation pillars are sequentially arranged in a direction away from the display region;
an insulative isolation layer, disposed on a side, away from the substrate, of the conductive isolation pillars and extending from the display region to the peripheral region, wherein an orthographic projection of the insulative isolation layer on the substrate at least covers an orthographic projection of each of the plurality of conductive isolation pillars on the substrate;
an organic material layer, disposed on a side, away from the substrate, of the insulative isolation layer and extending from the display region to the peripheral region, wherein the organic material layer is disconnected at the conductive isolation pillar; and
a first electrode, disposed on a side, away from the substrate, of the organic material layer and extending from the display region to the peripheral region, wherein the first electrode is disconnected at the conductive isolation pillar.

In some embodiments, the display panel further includes an enclosure dam, disposed within the peripheral region and disposed between the inorganic insulating layer and the insulative isolation layer, and the enclosure dam surrounding the aperture region; wherein
the plurality of conductive isolation pillars include a plurality of first conductive isolation pillars and a plurality of second conductive isolation pillars; wherein
the plurality of first conductive isolation pillars are disposed on a side, close to the display region, of the enclosure dam, and the plurality of first conductive isolation pillars are spaced sequentially in a direction away from the display region;
the plurality of second conductive isolation pillars are disposed on a side, away from the display region, of the enclosure dam, and the plurality of second conductive isolation pillars are spaced sequentially in a direction away from the display region; and
the orthographic projection of the insulative isolation layer on the substrate is at least partially not overlapped with an orthographic projection of the enclosure dam on the substrate

In some embodiments, a plurality of first grooves are disposed in the inorganic insulating layer, and the plurality of first grooves are disposed in a region between the enclosure dam and the display region; and
the plurality of first grooves are sequentially arranged in a direction away from the display region, and an orthographic projection of each of the plurality of first grooves on the substrate is not overlapped with an orthographic projection of each of the plurality of first conductive isolation pillars on the substrate.

In some embodiments, a first groove is disposed in the inorganic insulating layer, wherein the first groove is disposed in a region between the enclosure dam and the display region; and
an orthographic projection of each of the plurality of first conductive isolation pillars on the substrate is within an orthographic projection of the first groove on the substrate.

In some embodiments, a second groove is further disposed in the inorganic insulating layer, wherein the second groove are disposed in a region between the enclosure dam and the aperture region; and
an orthographic projection of each of the plurality of second conductive isolation pillars on the substrate is within an orthographic projection of the second groove on the substrate.

In some embodiments, the orthographic projection of the insulative isolation layer on the substrate is overlapped with the orthographic projection of the first groove and the orthographic projection of the second groove on the substrate.

In some embodiments, the display panel further includes an isolation structure, disposed between the inorganic insulating layer and the insulative isolation layer, and disposed within a non-display region of the peripheral region bordering the display region; wherein
the isolation structure includes a conductive portion and a planarization layer, wherein the conductive portion and the conductive isolation pillar are made of a same material and are disposed in a same layer, the planarization layer is disposed on a side, away from the substrate, of the conductive portion, and an orthographic projection of the planarization layer on the substrate covers an orthographic projection of the conductive portion on the substrate;
the orthographic projection of the planarization layer on the substrate is not overlapped with the conductive isolation pillar;
an isolation groove is disposed on a side, away from the substrate, of the planarization layer, and the orthographic projection of the insulative isolation layer on the substrate covers the orthographic projection of the planarization layer other than the isolation groove in the non-display region on the substrate;
a cross-sectional shape of the isolation groove perpendicular to the substrate includes a trapezoidal shape; and
the organic material layer or the organic material layer and the first electrode is disconnected at the isolation groove.

In some embodiments, the inorganic insulating layer includes a plurality of sub-layers, the plurality of sub-layers being sequentially stacked;
the display panel further includes a plurality of first spacer structures disposed in the peripheral region and disposed between adjacent sub-layers; and
the plurality of first spacer structures are in one-to-one correspondence with the plurality of second conductive isolation pillars, and an orthographic projection of each of the plurality of first spacer structures on the substrate is overlapped with an orthographic projection of each of the plurality of second conductive isolation pillars on the substrate.

In some embodiments, the display panel further includes a plurality of second spacer structures disposed in the peripheral region and disposed between adjacent sub-layers;
wherein the plurality of second spacer structures are in one-to-one correspondence with the plurality of first conductive isolation pillars, and each of the plurality of second spacer structures is overlapped with an orthographic projection of each of the plurality of first conductive isolation pillars on the substrate.

In some embodiments, the inorganic insulating layer includes a first sub-layer and a second sub-layer, the first sub-layer and the second sub-layer being stacked sequentially away from the substrate; wherein
the first spacer structure includes a first conductive pattern, and the second spacer structure includes a second conductive pattern;
the first conductive pattern and the second conductive pattern are made of a same material and are disposed in a same layer; and
the first conductive pattern and the second conductive pattern are disposed between the first sub-layer and the second sub-layer.

In some embodiments, the inorganic insulating layer further includes a third sub-layer disposed on a side, away from the substrate, of the second sub-layer back; wherein
the first spacer structure further includes a third conductive pattern, and the second spacer structure further includes a fourth conductive pattern;
the third conductive pattern and the fourth conductive pattern are made of a same material and are disposed in a same layer; and
the third conductive pattern and the fourth conductive pattern are disposed between the second sub-layer and the third sub-layer.

In some embodiments, centers of orthographic projections of the second conductive isolation pillar, the third conductive pattern, and the first conductive pattern on the substrate are coincident with each other;
any one side edge of the orthographic projection of the third conductive pattern on the substrate is retracted inwardly by 0.5 to 1 μm toward the center of the orthographic projection of the third conductive pattern relative to a corresponding side edge of the orthographic projection of the first conductive pattern on the substrate; and
any one side edge of the orthographic projection of the second conductive isolation pillar on the substrate is retracted inwardly by 0.5 to 1 μm toward the center of the orthographic projection of the second conductive isolation pillar relative to a corresponding side edge of the orthographic projection of third conductive pattern on the substrate.

In some embodiments, centers of orthographic projections of the first conductive isolation pillar, the fourth conductive pattern, and the second conductive pattern on the substrate are coincident with each other;
any one side edge of the orthographic projection of the fourth conductive pattern on the substrate is retracted inwardly by 0.5 to 1 μm toward the center of the orthographic projection of the fourth conductive pattern relative to a corresponding side edge of the orthographic projection of the second conductive pattern on the substrate; and
any one side edge of the orthographic projection of the first conductive isolation pillar on the substrate is retracted inwardly by 0.5 to 1 μm toward the center of the orthographic projection of the first conductive isolation pillar relative to a corresponding side edge of the orthographic projection of the fourth conductive pattern on the substrate.

In some embodiments, edge surfaces of the first conductive pattern, the second conductive pattern, the third conductive pattern, and the fourth conductive pattern are sloped surfaces;
wherein a slope angle of the sloped surface is 45°±10°

In some embodiments, the display panel further includes a plurality of third spacer structures disposed within the peripheral region and between the inorganic insulating layer and the conductive isolation pillar; wherein
the plurality of third spacer structures are in one-to-one correspondence with the plurality of first conductive isolation pillars and the plurality of second conductive isolation pillars, and each of the plurality of third spacer structures is overlapped with an orthographic projection of each of the plurality of first conductive isolation pillars on the substrate, and each of the plurality of third spacer structures is overlapped with an orthographic projection of each of the plurality of second conductive isolation pillars on the substrate; and
the orthographic projection of the insulative isolation layer on the substrate is overlapped with an orthographic projection of each of the plurality of third spacer structures on the substrate.

In some embodiments, a cross-sectional shape of the third spacer structure perpendicular to the substrate includes a trapezoidal shape;
wherein a bottom angle of the trapezoidal shape is 45°±10°.

In some embodiments, each of the plurality of first conductive isolation pillars is coincident with a center of the orthographic projection of each of the plurality of third spacer structures on the substrate;
each of the plurality of second conductive isolation pillars is coincident with the center of the orthographic projection of each of the plurality of third spacer structures on the substrate;
any one side edge of the orthographic projection of each of the plurality of first conductive isolation pillars on the substrate is retracted inwardly by 0.5 to 1 μm toward the center of the orthographic projection of each of the plurality of first conductive isolation pillars relative to a corresponding side edge of an orthographic projection of a top surface of the third spacer structure contacted with the first conductive isolation pillar on the substrate; and
any one side edge of the orthographic projection of each of the plurality of second conductive isolation pillars on the substrate is retracted inwardly by 0.5 to 1 μm toward a center of the orthographic projection of each of the plurality of second conductive isolation pillars relative to a corresponding side edge of an orthographic projection of a top surface of the third spacer structure contacted with the second conductive isolation pillar on the substrate.

In some embodiments, each of the plurality of conductive isolation pillar includes a first conductive layer, a second conductive layer, and a third conductive layer, the first conductive layer, the second conductive layer, and the third conductive layer being stacked sequentially away from the substrate; wherein
an edge surface of the second conductive layer is a first slope surface, and edge surfaces of the first conductive layer and the third conductive layer are second slope surfaces;
a slope angle of the first slope surface is less than a slope angle of the second slope surface; and
orthographic projections of the first conductive layer and the third conductive layer on the substrate both cover an orthographic projection of the second conductive layer on the substrate.

In some embodiments, the insulative isolation layer covers a side surface, away from the substrate, of the third conductive layer and the edge surfaces of the first conductive layer, the second conductive layer and the third conductive layer; and
a thickness of the insulative isolation layer ranges from 500 Å to 2000 Å.

A display device is provided by embodiments of the present disclosure. The display device includes the display panel described above.

### BRIEF DESCRIPTION OF DRAWINGS

The accompanying drawings are used to provide a further understanding of the embodiments of the present disclosure and form a portion of the description, and the accompanying drawings are used in conjunction with the embodiments of the present disclosure for the purpose of explaining the present disclosure, which do not constitute a limitation of the present disclosure. The above and other features and advantages become more apparent to those skilled in the art by describing the detailed example embodiments with reference to the accompanying drawings, in the accompanying drawings:

FIG. 1a is a schematic structural diagram of a light-emitting unit in an OLED display panel according to some embodiments of the present disclosure;

FIG. 1b is a partial cross-sectional view of a display region of an OLED display panel in an embodiment of the related art;

FIG. 1c is a schematic top view of an OLED display panel in the related art;

FIG. 1d is a schematic sectional view along the AA′ section line in FIG. 1c;

FIG. 1e is a schematic enlarged view of part B in FIG. 1d;

FIG. 1f is a schematic diagram of forming a conductive channel between a cathode and an isolation pillar in the related art;

FIG. 2a is a schematic top view of a peripheral region of an aperture region of a display panel according to some embodiments of the present disclosure;

FIG. 2b is a schematic sectional view along the CC′ section line in FIG. 2a;

FIG. 2c is a schematic enlarged view of part D in FIG. 2b;

FIG. 2d is another schematic sectional view along the CC′ section line in FIG. 2a;

FIG. 2e is a schematic enlarged view at the position of the enclosure dam in FIG. 2a;

FIG. 2f is a schematic sectional view along the EE′ section line in FIG. 2e;

FIG. 2g is another schematic sectional view along the CC′ section line in FIG. 2a;

FIG. 2h is still another schematic sectional view along the CC′ section line in FIG. 2a;

FIG. 2i is still another schematic sectional view along the CC′ section line in FIG. 2a;

FIG. 2j is still another schematic sectional view along the CC′ section line in FIG. 2a;

FIG. 2k is still another schematic sectional view along the CC′ section line in FIG. 2a;

FIG. 2l is still another schematic sectional view along the CC′ section line in FIG. 2a;

FIG. 2m is still another schematic sectional view along the CC′ section line in FIG. 2a;

FIG. 2n is still another schematic sectional view along the CC′ section line in FIG. 2a;

FIG. 2o is still another schematic sectional view along the CC′ section line in FIG. 2a;

FIG. 2p is a schematic sectional view of the first spacer structure and the second spacer structure according to some embodiments of the present disclosure;

FIG. 2q is another schematic sectional view of the first spacer structure and the second spacer structure according to some embodiments of the present disclosure;

FIG. 2r is still another schematic sectional view along the CC′ section line in FIG. 2a;

FIG. 2s is a partial cross-sectional view of a display region of a display panel according to some embodiments of the present disclosure;

FIG. 2t is a schematic top view of the distribution of conductive isolation pillars in the display panel according to some embodiments of the present disclosure; and

FIG. 3 is a schematic diagram of the manufacturing process of the conductive isolation pillar and the insulative isolation layer in embodiments of the present disclosure.

### DETAILED DESCRIPTION

In order to make those skilled in the art to better understand the technical solutions of the embodiments of the present disclosure, a display panel and a display device provided by the embodiments of the present disclosure are described in further detail below with reference to the accompanying drawings and specific embodiments.

The embodiments of the present disclosure are to be described more fully hereinafter with reference to the accompanying drawings, but the embodiments shown may be embodied in different forms and should not be construed as being limited to the embodiments of the present disclosure. Instead, these embodiments are provided for the purpose of making the present disclosure thorough and complete, and enabling those skilled in the art to fully understand the scope of the present disclosure.

The embodiments of the present disclosure are not limited to the embodiments illustrated in the accompanying drawings, but rather include modifications to the configurations formed based on the manufacturing process. Accordingly, the regions exemplified in the accompanying drawings have schematic properties, and the shapes of the regions shown in the drawings exemplify specific shapes of the region, but are not intended to construe any limitation.

The identical markings in the drawings indicate the same or similar structures, and thus their detailed descriptions are omitted. In addition, the accompanying drawings are only schematic illustrations of the present disclosure and are not necessarily drawn to scale.

The terms “a,” “an,” “the,” “said,” and “at least one” are used to indicate the presence of one or more elements, components, or the like; the terms “including” and “having” are used to indicate open inclusion and that there may be additional elements, components, or the like in addition to those listed; and the terms “first,” “second,” “third,” and the like are used only as markers and are not intended to be quantitative limitations of the subject matter.

In related art, the OLED display panel includes a driving backplane and an organic material layer. The organic material layer is disposed on a side of the driving backplane, and includes a plurality of light-emitting units. The light-emitting units include one or more series-connected light-emitting elements, and the light-emitting elements are organic light-emitting diodes. The organic light-emitting diode includes an anode, an organic material layer, and a cathode sequentially stacked in a direction away from the driving backplane. By applying an electrical signal to the anode and cathode, the organic material layer is driven to emit light, and the specific light-emitting principle of the light-emitting device is not described in detail herein.

The organic material layer of each light-emitting element emits monochrome light or white light through the color film to achieve color display, that is, the light-emitting elements share the same continuous organic material layer. The organic material layer emits white light or other monochromatic light, and the color film layer has a plurality of filtering portions in one-to-one correspondence with the plurality of light-emitting units. The filtering portion and the corresponding light-emitting unit constitute a sub-pixel, and a plurality of sub-pixels constitute a pixel. The colors of the light transmitted by different filtering portions are different, such that the light-emitting colors of different sub-pixels are different. The same pixel includes a plurality of sub-pixels with different colors, for example, a pixel includes three sub-pixels having luminescent colors of red, green, and blue. As a result, the color display is achieved by a plurality of pixels.

In the related art, the organic material layer is a continuous whole-layer structure, which is easy for leakage to occur between one light-emitting unit and the surrounding light-emitting units, resulting in cross-color. Each light-emitting unit includes a plurality of light-emitting elements connected in series, each light-emitting element of the same light-emitting unit shares an anode and a cathode, a plurality of light-emitting sub-layers are disposed between the anode and the cathode, and at least two of two adjacent light-emitting sub-layers are connected in series by a charge generation layer. Positive charges (holes) are transferred between the two adjacent light-emitting units through the charge generation layer. For example, in the case that the light-emitting unit corresponding to the red light-filtering portion in the color film layer emits light, the effect of the leakage causes the light-emitting unit corresponding to the green light-filtering portion in the color film layer to also emit light, resulting in a reduction in the purity of the light emitted by an individual pixel, and a reduction in the color gamut of the entire display panel.

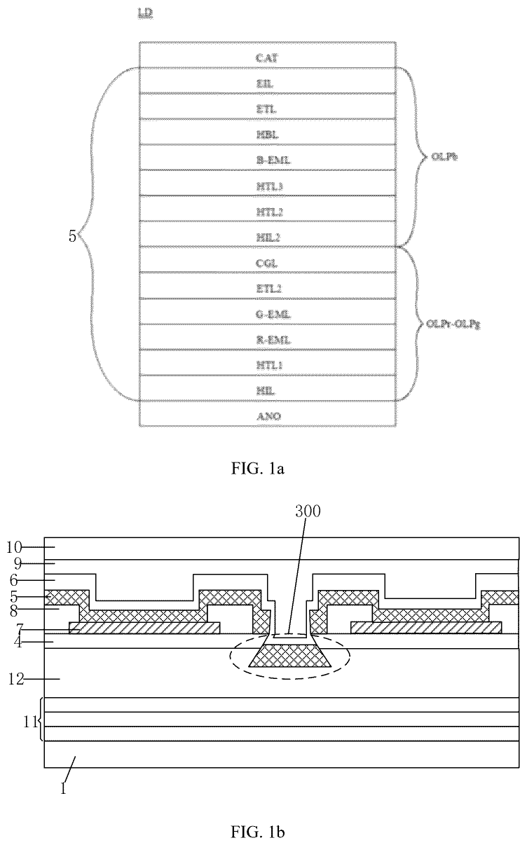

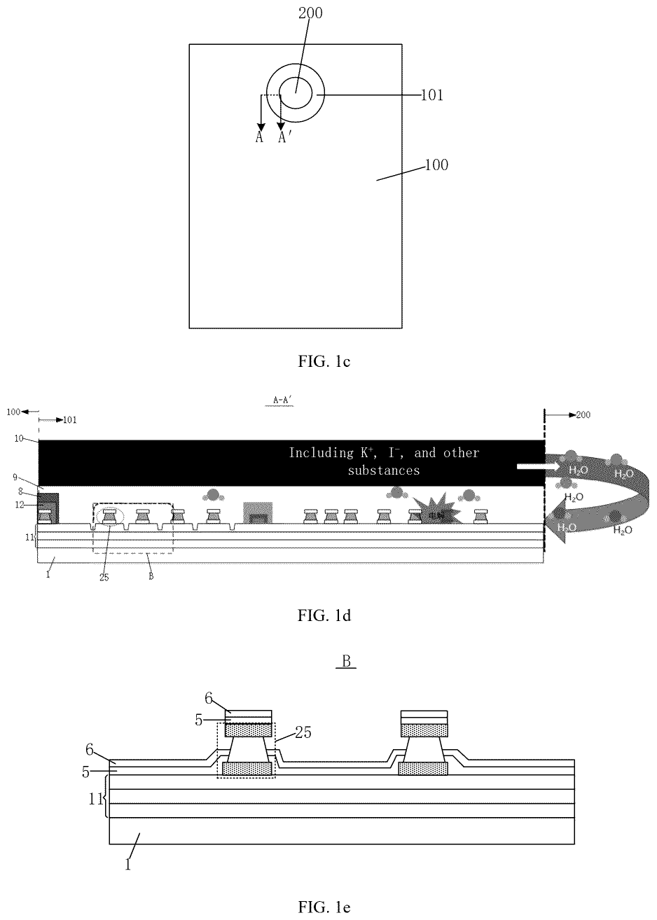

In some embodiments, referring to FIG. 1a, FIG. 1a is a schematic structural diagram of a light-emitting unit in the OLED display panel of an embodiment of the present disclosure. The light-emitting unit includes a plurality of light-emitting elements LDs connected in series, each of which includes an anode ANO, a cathode CAT, and a plurality of light-emitting sub-layers OLPs disposed between the anode ANO and the cathode CAT. The light-emitting elements LDs of the same light-emitting unit share the same anode ANO and the same cathode CAT, i.e., the same light-emitting unit have only one anode ANO and one cathode CAT.

For example, referring to FIG. 1a, the organic material layer 5 includes a plurality of sub-layers OLPs connected in series along a direction away from the driving backplane, and at least one sub-layer OLP is connected in series with an adjacent sub-layer OLP via the charge generation layer CGL. Each of the sub-layer OLPs emits light in the case that an electrical signal is applied to the anode ANO and the cathode CAT, and different sub-layer OLPs are used to emit light of different colors.

In some embodiments, referring to FIG. 1a, any one of the sub-layer OLPs includes a hole injection layer HIL, a hole transport layer HTL, a light-emitting material layer EML, an electron transport layer ETL, and an electron injection layer EIL arranged in a direction away from the driving backplane, and the specific light-emitting principle is not described in detail herein. The number of the hole injection layer HIL, the hole transport layer HTL, the electron transport layer ETL, and the electron injection layer EIL is not specifically limited herein. The adjacent light-emitting sub-layers OLP share one or more of the hole injection layer HIL, the hole transport layer HTL, the electron transport layer ETL, and the electron injection layer EIL. Further, at least two adjacent sub-layers OLP are provided with a charge generation layer CGL between them, thereby connecting the two sub-layers OLP in series.

In some embodiments, referring to FIG. 1a, the organic material layer 5 includes three sub-layers OLPs of different colors, i.e., a first sub-layer OLPr emitting red light, a second sub-layer OLPg emitting green light, and a third sub-layer OLPb emitting blue light. The first sub-layer OLPr, the second sub-layer OLPg, and the third sub-layer OLPb emits light simultaneously, such that the organic material layer OLP emits white light. The first sub-layer OLPr and the second sub-layer OLPg share a hole injection layer HIL, a hole transport layer HTL1, an electron transport layer ETL2, and an electron injection layer EIL, and a light-emitting material layer G-EML of the second sub-layer OLPg is disposed on a surface, away from the driving backplane, of the light-emitting material layer R-EML of the first sub-layer OLPr, thereby directly connecting the first sub-layer OLPr and the second sub-layer OLPg in series without having to arrange a dedicated charge generation layer. The second sub-layer OLPg is provided with a charge generation layer CGL on the surface, away from the driving backplane, of the second sub-layer OLPg. The third sub-layer OLPb shares the electron injection layer EIL with the first sub-layer OLPr and the second sub-layer OLPg, and the hole injection layer HIL2 of the third sub-layer OLPb is disposed on the surface, away from the driving backplane, of the charge generation layer CGL. The hole transport layer HTL2 and the hole transport layer HTL3 of the third sub-layer OLPb are stacked on a side, away from the driving backplane, of the charge generation layer CGL, and the third sub-layer OLPb is connected in series with the second sub-layer OLPg and the first sub-layer OLPr via the charge generation layer CGL. In addition, a hole first insulating layer HBL is disposed between the electron transport layer HYL of the third sub-layer OLPb and the light-emitting material layer BEML.

The structure of the organic material layer OL in FIG. 1a above is only an exemplary illustration and does not constitute a limitation of the film layer. The structure of the organic material layer OL includes only two sub-layers OLP, or more, or only one sub-layer OLP, as long as the organic material layer OL cooperate with the color film layer to achieve a color display.

In some embodiments, because the organic material layer is shared by each of the plurality of light-emitting units, the carriers (e.g., holes) of one light-emitting unit move to other light-emitting units, especially to adjacent light-emitting units, via a film layer such as a charge generating layer CGL, i.e., leakage occurs, which affects the purity of the light emitted and results in cross-color of colors.

In the related art, as shown in FIG. 1b, a partial cross-sectional view of an embodiment of a display region of an OLED display panel in the related art is shown in FIG. 1b. The OLED display panel includes a driving backplane, a plurality of anodes 7, a pixel definition layer 8, an organic material layer 5, a cathode (i.e., a first electrode 6), an encapsulation layer 9, and a polarizer 10. The pixel definition layer 8 is disposed on the same side of the driving backplane as the anode 7, and a plurality of first openings are disposed in the pixel definition layer 8, and the anode 7 is exposed at the first openings. The driving backplane includes a substrate 1, a pixel circuit 11, a planarization layer 12, and an insulative isolation layer 4 sequentially disposed on a side of the substrate 1, and the anode 7 is disposed on the side, away from the substrate 1, of the insulative isolation layer 4. The pixel definition layer 8 is disposed on a side, way from the substrate 1, of the anode 7 a. The organic material layer 5 is disposed on a side, away from the substrate 1, of the pixel definition layer 8, and the organic material layer 5 covers the entire display region. The cathode is disposed on the side, away from the substrate 1, of the organic material layer 5, and the cathode covers the organic material layer 5. Any one of the anodes 7 in the OLED display panel an organic material layer 5 corresponding to the anode 7, and the cathode constitute a light-emitting unit, and the pixel definition layer 8 provides the pixel definition for each of the plurality of light-emitting units, and defines a range of each of the plurality of light-emitting units. The encapsulation layer 9 is disposed on the side, away from the substrate 1, of the cathode for encapsulating the light-emitting unit. The polarizer 10 is disposed on the side, away from the substrate 1, of the encapsulation layer 9 for reducing the reflection of ambient light from the OLED display panel.

As shown in FIG. 1b, a second opening is also disposed in the pixel definition layer 8, the second opening is disposed within a region other than the region corresponding to the anode 7, and a recess 300 is disposed in the region of the insulative isolation layer 4 and the planarization layer 12 corresponding to the second opening, and the cross sectional shape perpendicular to the substrate of the recess 300 is a trapezoidal shape. The second opening and the trapezoidal recess 300, which is narrow at the top and wide at the bottom, disconnect at least a portion of the film layer in the organic material layer 5 recessed thereto, thereby preventing the carriers from moving between the light-emitting units, and avoiding cross-color due to leakage.

In some embodiments, as shown in FIG. 1c, FIG. 1d, FIG. 1e, and FIG. 1f, FIG. 1c is a schematic structural diagram of a top view of the OLED display panel in the related art; FIG. 1d is a schematic structural diagram of a sectional view along the AA′ section line in FIG. 1c; FIG. 1e is an enlarged schematic diagram of part B in FIG. 1d; and FIG. 1f is a schematic diagram of forming a conductive channel between a cathode and an isolation pillar in the related art. A through-hole 200 is disposed in the display region 100 of the OLED display panel through its thickness, and the through-hole 200 is used for mounting a camera. A plurality of isolation pillars 25 are disposed in a peripheral region 101 of the through-hole 200. The plurality of isolation pillars 25 are configured to isolate the organic material layer 5 and the cathode layer extending from the display region 100 to the peripheral region 101 of the through-hole 200. The isolation pillars 25 are conductive structures formed in a conductive layer in the driving backplane by one composition process. For example, the isolation pillars 25 are sandwich isolation structures including titanium/aluminum/titanium film layers sequentially stacked. As shown in FIG. 1d, the encapsulation layer 9 and the polarizer 10 extend from the display region 100 to cover the peripheral region 101 of the through-hole 200.

As shown in FIGS. 1e and 1f, during the reliability test of the OLED display panel, within the peripheral region 101 of the through-hole 200, the cathodes are connected to each other by the isolation pillar 25, i.e., the cathodes are indirectly conductive to each other through the aluminum metal in the isolation pillar 25, causing the entire peripheral region 101 of the through-hole 200 to be a negatively charged electrode. In a high temperature and high humidity environment, potassium ions (k+) within the polarizer 10 is transmitted with water vapor along the cross-section of the organic material layer 5 into the region where the isolation pillar 25 is located. Under the joint action of the negatively charged electrode and the moisture, the chemical substances within the polarizer 10 reacts with the inorganic encapsulation layer (e.g., silicon nitride) in the encapsulation layer 9, causing the inorganic encapsulation layer to be swollen by electrochemical corrosion and generating a hole, which leads to a failure of the encapsulation of the encapsulation layer 9 within the peripheral region 101 of the through-hole 200 bordering the display region 100. As a result, the GDSH occurs at the border of the display region 100 and the peripheral region 101 of the through-hole 200.

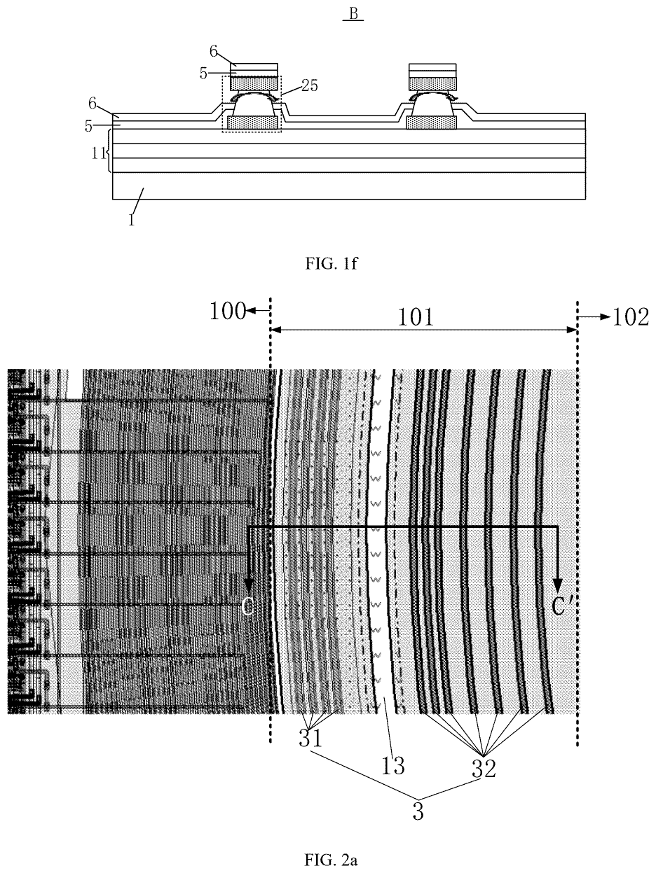

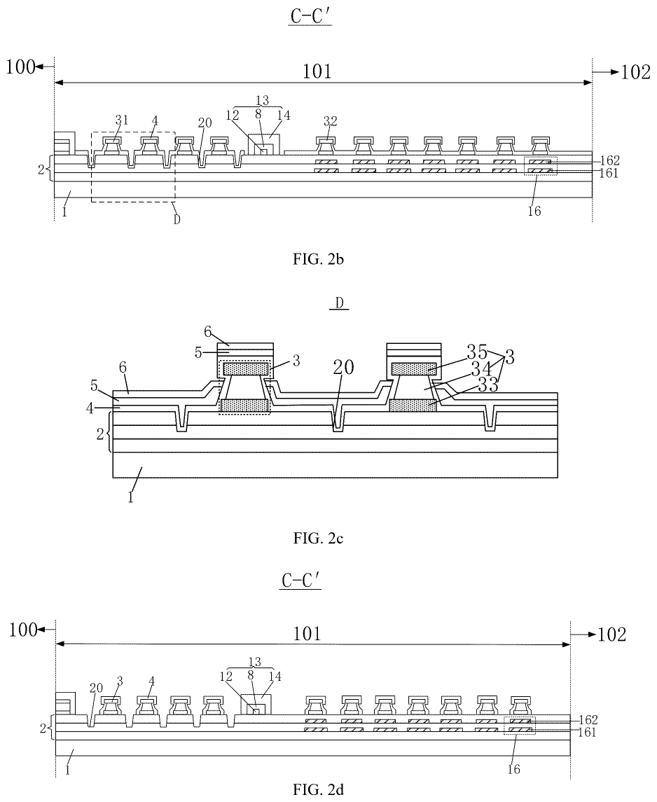

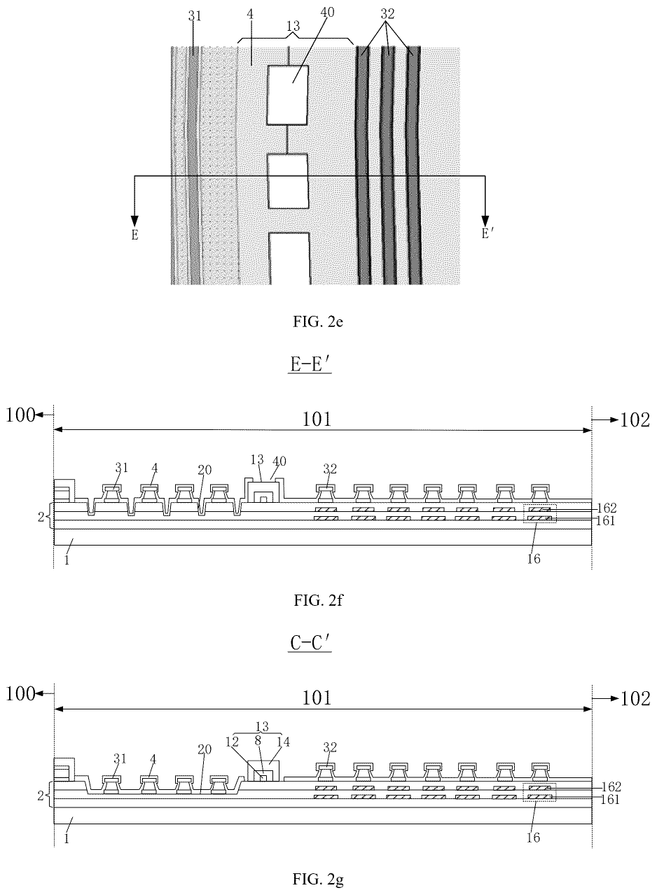

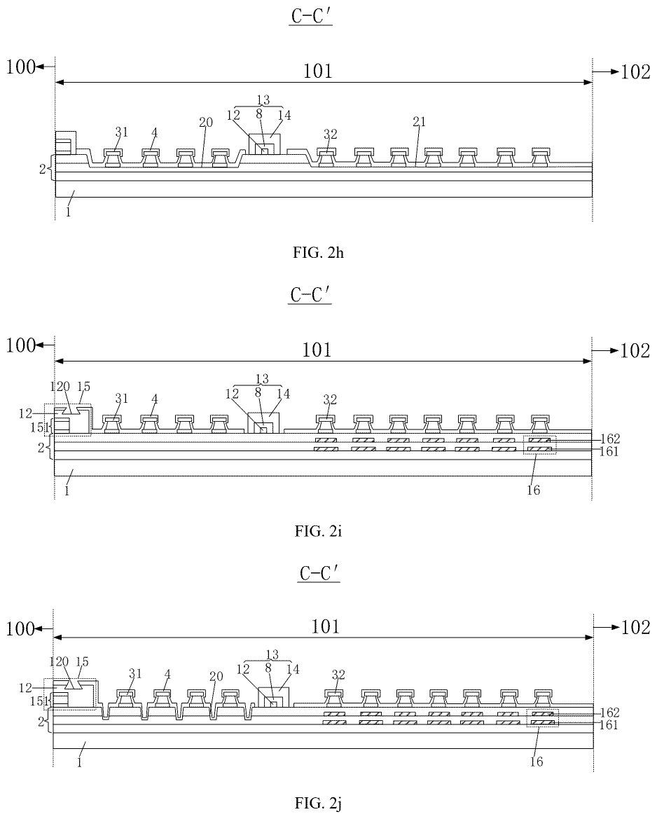

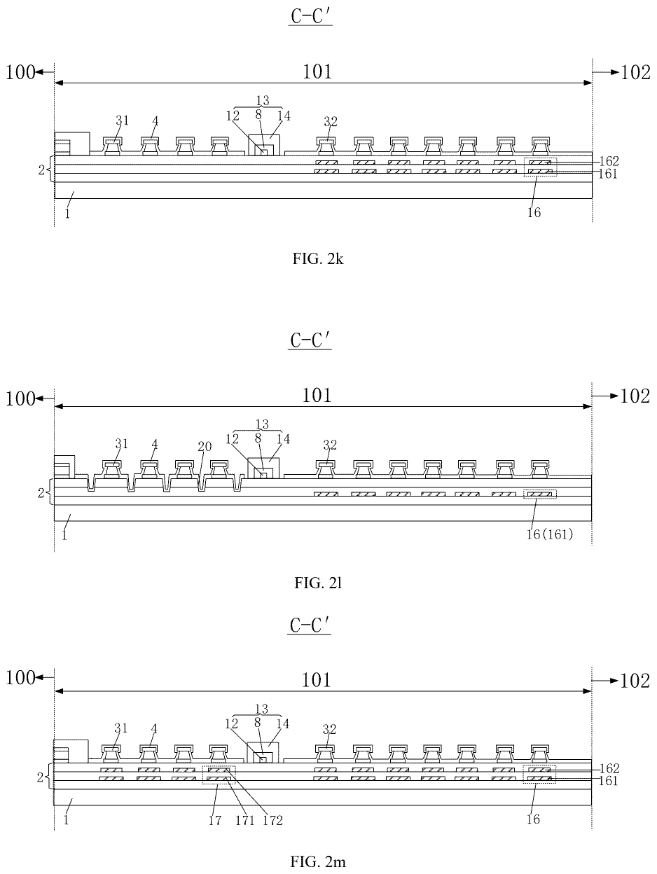

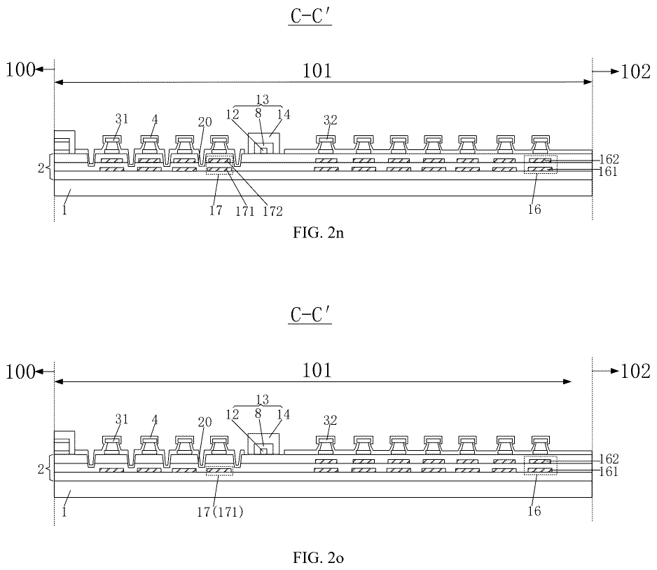

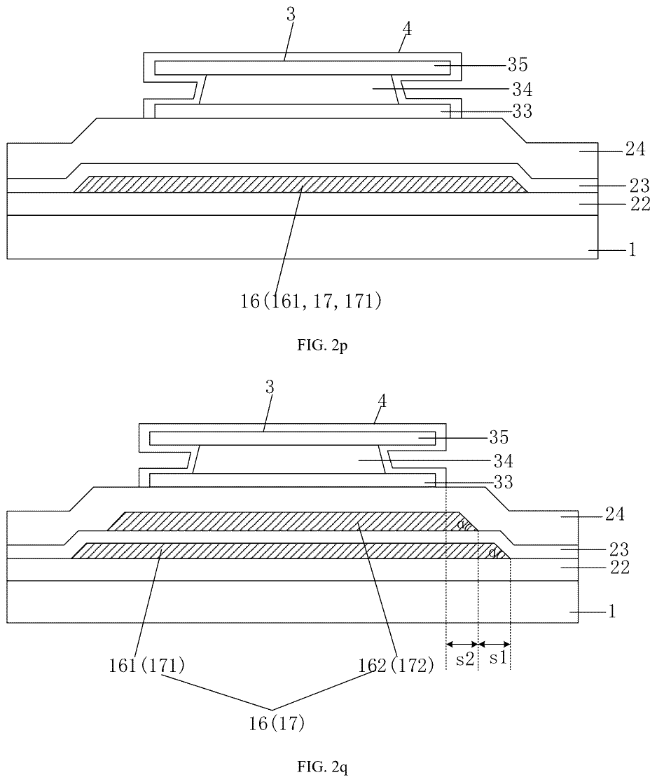

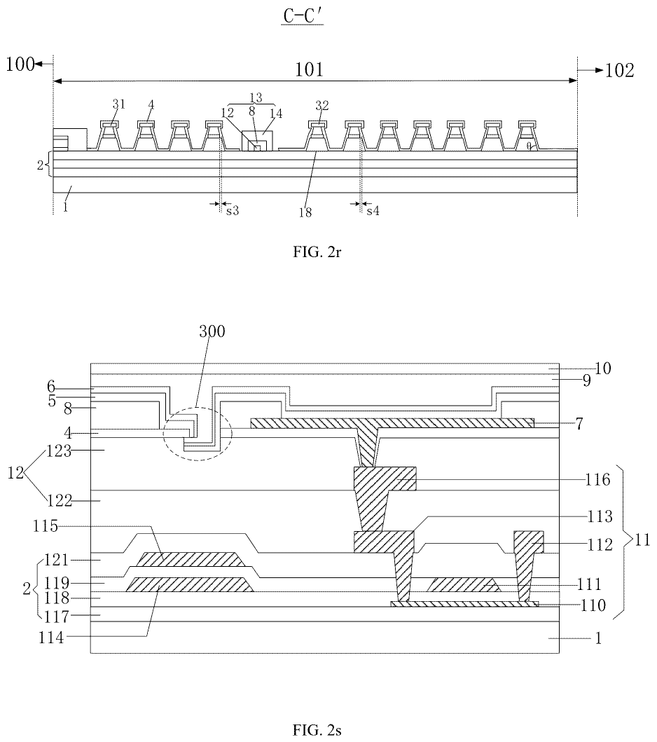

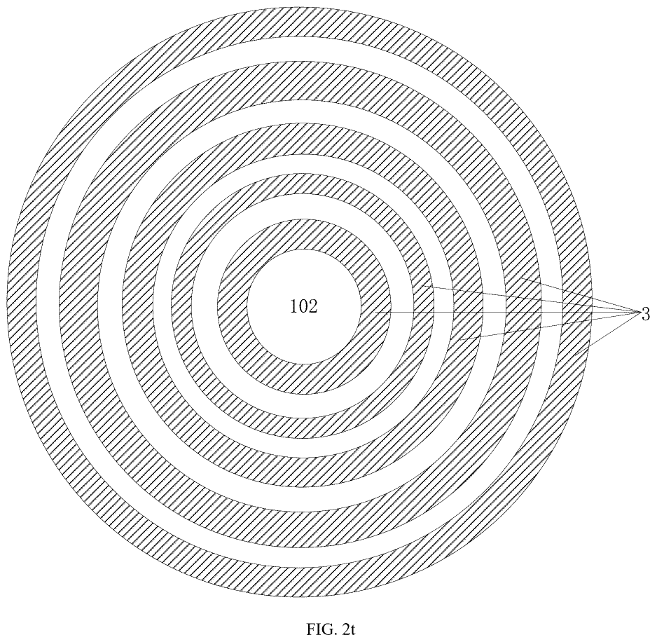

In order to solve the problem in the related art that electrochemical corrosion of the encapsulation layer fails due to failure to completely power off the cathode caused by the conductive isolation pillar during the reliability process, and consequently the GDSH appears at the border between the display region and the peripheral region of the through-hole, in a first aspect, embodiments of the present disclosure provide a display panel. Referring to FIGS. 2a to 2c, FIG. 2a is a schematic diagram of a top view of a peripheral region of an aperture region of a display panel according to some embodiments of the present disclosure; FIG. 2b is a schematic sectional view along the CC′ section line in FIG. 2a; and FIG. 2c is a schematic enlarged diagram of part D in FIG. 2b. The display panel has a display region 100 and an aperture region, the aperture region including an aperture region 102 and a peripheral region 101, the peripheral region 101 surrounding the periphery of the aperture region 102, and the display region 100 surrounding the peripheral region 101. The display panel includes: a substrate 1 disposed within the display region 100 and the peripheral region 101; an inorganic insulating layer 2 disposed on a side of the substrate 1, and extending from the display region 100 to the peripheral region 101; a plurality of conductive isolation pillars 3, disposed on a side, away from the substrate 1, of the inorganic insulating layer 2 and disposed within the peripheral region 101, wherein the plurality of conductive isolation pillars 3 are sequentially arranged in a direction away from the display region 100; an insulative isolation layer 4 disposed on a side, away from the substrate 1, of the conductive isolation pillars 3 and extending from the display region 100 to the peripheral region 101, wherein an orthographic projection of the insulative isolation layer 4 on the substrate 1 at least covers an orthographic projection of each of the plurality of conductive isolation pillars 3 on the substrate 1; an organic material layer 5 disposed on a side, away from the substrate 1, of the insulative isolation layer 4 and extending from the display region 100 to the peripheral region 101, wherein the organic material layer 5 is disconnected at the conductive isolation pillar 3; and a first electrode 6 disposed on a side, away from the substrate 1, of the organic material layer 5 and extending from the display region 100 to the peripheral region 101, wherein the first electrode 6 is disconnected at the conductive isolation pillar 3.

The first electrode 6 is a cathode. Referring to FIG. 2s, FIG. 2s is a partial cross-sectional view of a display region of a display panel according to some embodiments of the present disclosure. The display panel further includes a plurality of anodes 7, a pixel definition layer 8, an encapsulation layer 9, and a polarizer 10, and a pixel circuit 11, and a planarization layer 12 that are sequentially disposed on a side, away from the substrate 1, of the substrate 1 in a direction. The pixel circuit 11 is disposed within the display region 100, and the planarization layer 12 extends from the display region 100 to the peripheral region 101. The pixel circuit 11 includes a transistor and a capacitor. The transistor includes an active layer 110, a gate electrode 111, a source electrode 112, and a drain electrode 113 that are disposed in the same layer. The capacitor includes a first electrode plate 114 and a second electrode plate 115. The pixel circuit 11 further includes a conductive connection structure 116. The active layer 110, the gate electrode 111, the source electrode 112, and the drain electrode 113 that are disposed in the same layer, and the conductive connection structure 116 are disposed in a direction away from the substrate 1. The gate electrode 111 is disposed in the same layer as the first electrode plate 114. The conductive connection structure 116 connects the anode 7 to the drain electrode 113. The pixel circuit 11 further includes a buffer layer 117, a first gate insulating layer 118, a second gate insulating layer 119, and an intermediate dielectric layer 121. The buffer layer 117 is disposed between the active layer 110 and the substrate 1, the first gate insulating layer 118 is disposed between the active layer 110 and the gate electrode 111, and the second gate insulating layer 119 is disposed between the first electrode plate 114 and the second electrode plate 115. The intermediate dielectric layer 121 is disposed between the second electrode plate 115 and the source electrode 112 and drain electrode 113 in the same layer. The planarization layer 12 includes a first planarization layer 122 and a second planarization layer 123. The first planarization layer 122 is disposed between the source electrode 112 and the drain electrode 113 in the same layer and the conductive connection structure 116. The second planarization layer 123 and the insulative isolation layer 4 are disposed between the anode 7 and the conductive connection structure 116. The inorganic insulating layer 2 includes a buffer layer 117, a first gate insulating layer 118, a second gate insulating layer 119, and an intermediate dielectric layer 121. The insulative isolation layer 4 is disposed on a side, away from the substrate 1, of the planarization layer 12, and the anode 7 is disposed on a side, away from the substrate 1, of the insulative isolation layer 4. The pixel definition layer 8 is disposed on the side, away from the substrate 1, of the anode 7, and the organic material layer 5 is disposed on a side, away from the substrate 1, of the pixel definition layer 8. An opening is disposed in the pixel definition layer 8, the anode 7 is exposed at the opening, and a portion of the organic material layer 5 disposed in the opening of the pixel definition layer 8 emits light under the action of the electric field formed between the anode 7 and the first electrode 6. The encapsulation layer 9 is disposed on a side, away from the substrate 1, of the first electrode 6. The polarizer 10 is disposed on a side, away from the substrate 1, of the encapsulation layer 9. The anode 7 is disposed within the display region 100. The pixel definition layer 8 is disposed in the display region 100. The planarization layer 12 extends from the display region 100 to a non-display region bordering the display region 100 within the peripheral region 101. The encapsulation layer 9 and the polarizer 10 extend from the display region 100 to cover the peripheral region 101. The conductive isolation pillar 3 is formed in a conductive layer in the pixel circuit 11 by one composition process. The insulative isolation layer 4 extends from the display region 100 to the peripheral region 101.

In some embodiments, referring to FIG. 2t, FIG. 2t is schematic top view of distribution of conductive isolation pillars in the display panel according to some embodiments of the present disclosure. The shape of the orthographic projection of each of the plurality of conductive isolation pillars 3 on the substrate 1 is a circular shape, the orthographic projection of each of the plurality of conductive isolation pillars 3 on the substrate 1 surrounds the periphery of the aperture region 102, and the plurality of conductive isolation pillars 3 form a concentric ring groups centered on the aperture region 102.

By disposing an insulative isolation layer 4 on the side, away from the substrate 1, of the conductive isolation pillar 3, and the orthographic projection of the insulative isolation layer 4 on the substrate 1 covers at least the orthographic projection of the conductive isolation pillar 3 on the substrate 1. Additionally, the provision of the insulative isolation layer 4 elevates the height of the conductive isolation pillar 3, thereby contributing to isolating the organic material layer 5 and the first electrode 6 extending from the display region 100 to the peripheral region 101. On the other hand, the insulative isolation layer 4 blocks the conductive connection between the first electrode 6 and the conductive isolation pillar 3, such that the peripheral region 101 of the display panel in the reliability test does not become a charged electrode (i.e., with the voltage of the first electrode 6), and the reaction of the chemical substances within the polarizer 10 in the display panel with the inorganic encapsulation layer in the encapsulation layer 9 is avoided. That is, the inorganic encapsulation layer is prevented from being chemically reacted by electrochemical corrosion, and the failure of the encapsulation layer 9 at the border between the display region 100 and the peripheral region 101, thereby avoiding the phenomenon of GDSH at the border of the display region 100 and the peripheral region 101.

In some embodiments, referring to FIGS. 2b and 2c, the orthographic projection of the insulative isolation layer 4 on the substrate 1 covers the conductive isolation pillars 3 and the region within the peripheral region 101 other than the conductive isolation pillars 3.

In some embodiments, referring to FIG. 2d, FIG. 2d is another schematic sectional view along the CC′ section line in FIG. 2a. The orthographic projection of the insulative isolation layer 4 on the substrate 1 covers only the conductive isolation pillars 3.

In some embodiments, referring to FIGS. 2a and 2b, the display panel further includes an enclosure dam 13. The enclosure dam 13 is disposed in the peripheral region 101 and between the inorganic insulating layer 2 and the insulative isolation layer 4, and the enclosure dam 13 surrounds the periphery of the aperture region 102. The plurality of conductive isolation pillars 3 includes a plurality of first conductive isolation pillars 31 and a plurality of second conductive isolation pillars 32. The plurality of first conductive isolation pillars 31 are disposed on a side, close to the display region 100, of the enclosure dam 13, and the plurality of first conductive isolation pillars 31 are spaced apart sequentially in a direction away from the display region 100. The plurality of second conductive isolation pillars 32 are disposed on the side, away from the display region 100, of the enclosure dam 13, and the plurality of second conductive isolation pillars 32 are spaced apart sequentially in a direction away from the display region 100, and the orthographic projection of the insulative isolation layer 4 on the substrate 1 is at least partially not overlapped with the orthographic projection of the enclosure dam 13 on the substrate 1.

In some embodiments, the display panel further includes a first planarization layer 14 disposed between the first electrode 6 and the encapsulation layer 9. The enclosure dam 13 is formed by organic film layers of the planarization layer 12, the pixel-defining layer 8, and the first planarization layer 14 within the display region 100 disposed in the same layer and having the same material sequentially stacked away from the substrate 1, and the organic film layer disposed in the same layer and having material as the pixel-defining layer 8 encapsulates the organic film layer disposed in the same layer and having the same material as the planarization layer 12, and the organic film layer disposed in the same layer and having the same material as the first planarization layer 14 encapsulates the organic film layer disposed in the same layer and having the same material as the pixel-defining layer 8. The enclosure dam 13 is formed by stacking the organic material film layers, such that the enclosure dam 13 is made higher or thicker, so as to form a barrier to the organic encapsulation layer material in the encapsulation layer 9, and prevent the organic encapsulation layer material from overflowing to the side, away from the display region 100, of the enclosure dam 13 during encapsulation. That is, the organic encapsulation layer in the encapsulation layer 9 extends from the display region 100 to cover the region the side, close to the display region 100, of the enclosure dam 13, and the organic encapsulation layer does not extend beyond the enclosure dam 13. The inorganic encapsulation layer in the encapsulation layer 9 extends from the display region 100 to cover the entire perimeter region 101.

The organic material forming the enclosure dam 13 needs to be deflated, and the insulative isolation layer 4 is made of an inorganic insulating material, such as a silicon nitride, silicon oxide, or silicon nitride oxide material. In the case that the insulative isolation layer 4 covers the enclosure dam 13 completely, outgassing of the organic material causes the insulative isolation layer 4 to peel off, resulting in subsequent peeling of particles that contaminate the display region 100 and become defective. By arranging the orthographic projection of the insulative isolation layer 4 on the substrate 1 and the orthographic projection of the enclosure dam 13 on the substrate 1 to be at least partially not overlapped, it is possible to avoid that the insulative isolation layer 4 blocks the outgassing of the organic material, thus preventing the display panel from being defective.

In some embodiments, referring to FIG. 2b, the orthographic projection of the insulative isolation layer 4 on the substrate 1 is not overlapped with the orthographic projection of the enclosure dam 13 on the substrate 1.

In some embodiments, referring to FIGS. 2e and 2f, FIG. 2e is a schematic enlarged view at the position of the enclosure dam in FIG. 2a; and FIG. 2f is a schematic sectional view along the EE′ section line in FIG. 2e. The opening 40 is disposed in the region of the insulative isolation layer 4 that is overlapped with the enclosure dam 13, and the enclosure dam 13 is exposed at the opening 40, thereby facilitating the venting of organic material from the enclosure dam 13 during the preparation process.

In some embodiments, referring to FIG. 2b, FIG. 2c, FIG. 2d, and FIG. 2f, a plurality of first grooves 20 are disposed in the inorganic insulating layer 2, the plurality of first grooves 20 being disposed in a region between the enclosure dam 13 and the display region 100. The plurality of first grooves 20 are sequentially arranged in a direction away from the display region 100, and the orthographic projection of the plurality of first grooves 20 on the substrate 1 is not overlapped with the orthographic projection of the first conductive isolation pillar 31 on the substrate 1.

The arrangement of the plurality of first grooves 20 in the inorganic insulating layer 2 forms a barrier to the organic encapsulation layer material in the encapsulation layer 9, preventing the organic encapsulation layer material from overflowing to the side, away from the display region 100, of the enclosure dam 13 during encapsulation.

In some embodiments, referring to FIG. 2g, FIG. 2g is another schematic sectional view along the CC′ section line in FIG. 2a. The first groove 20 is disposed in the inorganic insulating layer 2, the first groove 20 is disposed within a region between the enclosure dam 13 and the display region 100, and a plurality of first conductive isolation pillars 31 are disposed within the region of the first groove 20's orthographic projection on the substrate 1.

Referring to FIG. 2g, the first groove 20 is a large groove between the enclosure dam 13 and the display region 100. The large groove further forms a barrier to the organic encapsulation layer material in the encapsulation layer 9, preventing the organic encapsulation layer material from spilling out to the side, away from the display region 100, of the enclosure dam 13 during encapsulation.

In some embodiments, referring to FIG. 2h, FIG. 2h is still another schematic sectional view along the CC′ section line in FIG. 2a. The second groove 21 is also disposed in the inorganic insulating layer 2, the second groove 21 being disposed within the region between the enclosure dam 13 and the aperture region 102, and the plurality of second conductive isolation pillars 32 are disposed within the region of the orthographic projection of the second groove 21 on the substrate 1.

Referring to FIG. 2h, the second groove 21 is a large groove between the enclosure dam 13 and the open hole region 102. The large groove facilitates thinning the thickness of the inorganic insulating layer 2 that needs to be cut when cutting to form the open hole region 102, thereby enhancing the cutting quality of the open hole region 102.

In some embodiments, referring to FIG. 2g and FIG. 2h, the orthographic projection of the insulative isolation layer 4 on the substrate 1 is overlapped with the orthographic projection of the first groove 20 and the second groove 21 on the substrate 1.

In some embodiments, referring to FIG. 2i, FIG. 2i is another schematic sectional view along the CC′ section line in FIG. 2a. The display panel further includes an isolation structure 15, disposed between the inorganic insulating layer 2 and the insulative isolation layer 4, and within a non-display region of the peripheral region 101 bordering the display region 100. The isolation structure 15 includes a conductive portion 151 and a planarization layer 12. The conductive portion 151 and the conductive isolation pillar are made of the same material and are disposed in the same layer. The planarization layer 12 is disposed on a side, away from the substrate 1, of the conductive portion 151, and an orthographic projection of the planarization layer 12 on the substrate 1 covers the orthographic projection of the conductive portion 151 on the substrate 1, and the orthographic projection of the planarization layer 12 on the substrate 1 is not overlapped with the conductive isolation pillar 3. The isolation groove 120 is disposed on a side, away from the substrate 1, of the planarization layer 12, and the orthographic projection of the insulative isolation layer 4 on the substrate 1 covers the orthographic projection of the planarization layer 12 on the substrate 1 other than the isolation groove 120 in the non-displayed region, and the cross-sectional shape of the isolation groove 120 perpendicular to the substrate 1 includes a trapezoidal shape, and the layer 5 of the organic material, or the layer 5 of the organic material, and the first electrodes 6 are disconnected at the isolation groove 120.

The isolation structure 15 serves to isolate the organic material layer 5 and the first electrode 6 (i.e., the cathode), thereby further blocking the conductive connection between the first electrode 6 and the conductive isolation pillar 3 in the peripheral region 101, thereby enhancing the disconnection effect of the first electrode 6 in the peripheral region 101, and further avoiding the phenomenon of GDSH at the border between the display region 100 with the peripheral region 101.

In some embodiments, referring to FIG. 2s, the conductive portion 151 and the conductive connection structure 116 disposed in the display region 100 are made of the same material and are disposed in the same layer. The planarization layer 12 is a planarization layer 12 of a portion of a non-display region bordering the display region 100 extending from the display region 100 to the peripheral region 101.

In some embodiments, referring to FIG. 2i and FIG. 2k, FIG. 2k is still another schematic sectional view along the CC′ section line in FIG. 2a. The grooves are not disposed in the inorganic insulating layer 2. The absence of grooves in the inorganic insulating layer 2 avoids the risk of reliability failure due to metallic residues and organic layer residues in the grooves.

In some embodiments, referring to FIG. 2j, FIG. 2j is still another schematic sectional view along the CC′ section line in FIG. 2a. Based on the arrangement of the isolation structure 15, a plurality of first grooves 20 are disposed in the inorganic insulating layer 2, the plurality of first grooves 20 being disposed within the region between the enclosure dam 13 and the display region 100. The first grooves 20 forms a barrier to the organic encapsulation layer material in the encapsulation layer 9, preventing the organic encapsulation layer material from overflowing to a side, away from the display region 100, of the enclosure dam 13 during encapsulation.

In some embodiments, with reference to FIG. 2b, FIG. 2d, FIG. 2f, FIG. 2g, FIG. 2i, FIG. 2j, FIG. 2k, and FIG. 2l, FIG. 2l is another schematic sectional view along the CC′ section line in FIG. 2a. The inorganic insulating layer 2 includes a plurality of sub-layers, wherein the plurality of sub-layers are sequentially stacked. The display panel further includes a plurality of first spacer structures 16 disposed within the peripheral region 101 and between adjacent sub-layers, the plurality of first spacer structures 16 being in one-to-one correspondence with the plurality of second conductive isolation pillars 32, and the orthographic projection of the first spacer structures 16 on the substrate 1 being overlapped with the orthographic projection of the second conductive isolation pillars 32 on the substrate 1.

The first spacer structure 16 is provided to elevate the second conductive isolation pillar 32, so as to facilitate the deposition of the inorganic encapsulation layer in the subsequent encapsulation layer 9, and reduce the risk of fracture of the inorganic encapsulation layer.

In some embodiments, with reference to FIG. 2m, FIG. 2n, and FIG. 2o, FIG. 2m is another schematic sectional view along the CC′ section line in FIG. 2a; FIG. 2n is still another schematic sectional view along the CC′ section line in FIG. 2a; and FIG. 2o is still another schematic sectional view along the CC′ section line in FIG. 2a. The display panel further includes a plurality of second spacer structures 17 disposed within the peripheral region 101 and between adjacent sub-layers, the plurality of second spacer structures 17 in one-to-one correspondence with the plurality of first conductive isolation pillars 31, and the second spacer structures 17 being overlapped with the orthographic projection of the first conductive isolation pillars 31 on the substrate 1.

With the second spacer structure 17, the first conductive isolation pillars 31 may be raised up. In this way, a barrier is formed against the organic encapsulation layer material in the encapsulation layer 9, which prevents the organic encapsulation layer material from overflowing into the side, away from the display region 100, of the enclosure dam 13 during encapsulation. Additionally, it is conducive to the deposition of the inorganic encapsulation layer in the subsequent encapsulation layer 9, which reduces the risk of fracture of the inorganic encapsulation layer.

In some embodiments, with reference to FIG. 2o, FIG. 2l, and FIG. 2p, FIG. 2p is a schematic sectional view of the first spacer structure and the second spacer structure according to some embodiments of the present disclosure. The inorganic insulating layer 2 includes a first sub-layer 22 and a second sub-layer 23, wherein the first sub-layer 22 and the second sub-layer 23 are sequentially stacked away from the substrate 1. The first spacer structure 16 includes a first conductive pattern 161, and the second spacer structure 17 includes a second conductive pattern 171. The first conductive pattern 161 and the second conductive pattern 171 are made of the same material and are disposed in the same layer. The first conductive pattern 161 and the second conductive patterns 171 are disposed between the first sub-layer 22 and the second sub-layer 23.

Referring to FIG. 2s, the first sub-layer 22 is a first gate insulating layer 118 in the pixel circuit 11, and the second sub-layer 23 is a second gate insulating layer 119 in the pixel circuit 11. The first conductive pattern 161 and the second conductive pattern 171 are made of the same material and are formed by one composition process as the gate 111 and the first electrode plate 114 in the pixel circuit 11. The first conductive pattern 161 and the second conductive pattern 171 are suspended and serve only to elevate the second conductive isolation pillar 32 and the first conductive isolation pillar 31 respectively.

In some embodiments, with reference to FIG. 2b, FIG. 2d, FIG. 2f, FIG. 2g, FIG. 2i, FIG. 2j, FIG. 2k, FIG. 2m, FIG. 2o, FIG. 2n, and FIG. 2q, FIG. 2q is another schematic sectional view of the first spacer structure and the second spacer structure according to some embodiments of the present disclosure. The inorganic insulating layer 2 further includes a third sub-layer 24 disposed on a side, away from the substrate 1, of the second sub-layer 23. The first spacer structure 16 further includes a third conductive pattern 162, and the second spacer structure 17 further includes a fourth conductive pattern 172. The third conductive pattern 162 and the fourth conductive pattern 172 are made of the same material and are disposed in the same layer. The third conductive pattern 162 and the fourth conductive pattern 172 are disposed between the second sub-layer 23 and the third sub-layer 24.

Referring to FIG. 2s, the third conductive pattern 162 and the fourth conductive pattern 172 further elevate the second conductive isolation pillar 32 and the first conductive isolation pillar 31. The third sub-layer 24 is an intermediate dielectric layer 121 in the pixel circuit 11, and the third conductive pattern 162 and the fourth conductive pattern 172 are made of the same material as the second polar plate 115 in the pixel circuit 11 and are formed by one composition process formation. The third conductive pattern 162 and the fourth conductive pattern 172 are suspended and serve only to elevate the second conductive isolation pillar 32 and the first conductive isolation pillar 31 respectively.

In some embodiments, referring to FIG. 2q, centers of orthographic projections of the second conductive isolation pillar 32, the third conductive pattern 162, and the first conductive pattern 161 on the substrate 1 are coincident with each other, and any one side edge of the orthographic projection of the third conductive pattern 162 on the substrate 1 is retracted inwardly by a distance s1 of 0.5 to 1 μm toward the center of the orthographic projection of the third conductive pattern 162 relative to a corresponding side edge of the orthographic projection of the first conductive pattern 161 on the substrate 1. Any one side edge of the orthographic projection of the second conductive isolation pillar 32 on the substrate 1 is retracted inwardly by a distance s2 of 0.5 to 1 μm toward the center of the orthographic projection of the second conductive isolation pillar 32 relative to a corresponding side edge of the orthographic projection of the third conductive pattern 162 on the substrate 1.

In some embodiments, referring to FIG. 2q, the edge surfaces of both the first conductive pattern 161 and the third conductive pattern 162 are sloped surfaces, wherein a slope angle α of the sloped surface is 45°±10°.

In this way, it is possible to make the peripheral raised sloped surface formed by raising of the second conductive isolation pillar 32 by the first spacer structure 16 relatively gentle, thereby facilitating the deposition of the inorganic encapsulation layer in the subsequent encapsulation layer 9, and reducing the risk of fracture of the inorganic encapsulation layer.

In some embodiments, referring to FIG. 2q, the centers of orthographic projections of the first conductive isolation pillar 31, the fourth conductive pattern 172, and the second conductive pattern 171 on the substrate 1 are coincident with each other, and any one side edge of the orthographic projection of the fourth conductive pattern 172 on the substrate 1 is retracted inwardly by a distance s1 of 0.5 to 1 μm toward the center of the orthographic projection of the fourth conductive pattern 172 relative to a corresponding side edge of the orthographic projection of the second conductive pattern 171 on the substrate 1. Any one side edge of the orthographic projection of the first conductive isolation pillar 31 on the substrate 1 is retracted inwardly by a distance s2 of 0.5 to 1 μm toward the center of the orthographic projection of the first conductive isolation pillar 31 relative to a corresponding side edge of the orthographic projection of the fourth conductive pattern 172 on the substrate 1.

In some embodiments, referring to FIG. 2q, the edge surfaces of both the second conductive pattern 171 and the fourth conductive pattern 172 are sloped surfaces, and a slope angle αof the sloped surface is 45°±10°.

The above slope angle α and inward reduction arrangement make the surrounding raised slope surface formed by the raising of the first conductive isolation pillar 31 by the second spacer structure 17 relatively gentle, thereby facilitating the deposition of the inorganic encapsulation layer in the subsequent encapsulation layer 9 and reducing the risk of fracture of the inorganic encapsulation layer.

In some embodiments, referring to FIG. 2r, FIG. 2r is still another schematic sectional view along the CC′ section line in FIG. 2a. The display panel further includes a plurality of third spacer structures 18 disposed within the peripheral region 101 and between the inorganic insulating layer 2 and the conductive isolation pillar 3. The plurality of third spacer structures 18 are in one-to-one correspondence with the plurality of first conductive isolation pillars 31 and the plurality of second conductive isolation pillars 32, and the third spacer structures 18 are overlapped with the orthographic projection of the first conductive isolation pillars 31 on the substrate 1, and the third spacer structures 18 are overlapped with the orthographic projection of the second conductive isolation pillars 32 on the substrate 1. The orthographic projection of the insulative isolation layer 4 on the substrate 1 is overlapped with the orthographic projection of the third spacer structure 18 on the substrate 1.

The third spacer structure 18 is capable of raising the second conductive isolation pillar 32, thereby facilitating the deposition of the inorganic encapsulation layer in the subsequent encapsulation layer 9 and reducing the risk of fracture of the inorganic encapsulation layer. The third elevation structure 18 is also capable of raising the first conductive isolation pillar 31, such that, in one aspect, the organic encapsulation layer material in the encapsulation layer 9 forms a barrier to prevent the organic encapsulation layer material from overflowing into the side, away from the display region 100, of the enclosure dam 13 during encapsulation, and in another aspect, it is conducive to the deposition of the inorganic encapsulation layer in the subsequent encapsulation layer 9, and reduces the risk of fracture of the inorganic encapsulation layer.

In some embodiments, referring to FIG. 2r, the cross-sectional shape of the third spacer structure 18 perpendicular to the substrate 1 includes a trapezoidal shape, wherein the bottom angle θ of the trapezoidal shape is 45°±10°.

In some embodiments, referring to FIG. 2r, each of the plurality of first conductive isolation pillars 31 is coincident with a center of the orthographic projection of each of the plurality of third spacer structures 18 on the substrate1, and each of the plurality of second conductive isolation pillars 32 is coincident with the center of the orthographic projection of each of the plurality of third spacer structures 18 on the substrate1. Any one side edge of the orthographic projection of each of the plurality of first conductive isolation pillars 31 on the substrate 1 is retracted inwardly by a distance s3 of 0.5 to 1 μm toward the center of the orthographic projection of each of the plurality of first conductive isolation pillars 31 relative to a corresponding side edge of the orthographic projection of the top surface of the third spacer structure 18 contacted with the first conductive isolation pillar 31 on the substrate 1. Any one side edge of the orthographic projection of each of the plurality of second conductive isolation pillars 32 on the substrate 1 is retracted inwardly s3 of 0.5 to 1 μm toward a center of the orthographic projection of each of the plurality of second conductive isolation pillars 32 relative to a corresponding side edge of an orthographic projection of the second conductive isolation pillar 32 contacted with the second conductive isolation pillar 31 on the substrate 1.

The above bottom angle θ and the inward contraction arrangement makes the peripheral raised slope surface formed by the raising of the first conductive isolation pillar 31 and the second conductive isolation pillar 32 by the third spacer structure 18 relatively gentle, thereby facilitating the deposition of the inorganic encapsulation layer in the subsequent encapsulation layer 9 and reducing the risk of fracture of the inorganic encapsulation layer.

In some embodiments, referring to FIGS. 2r and 2s, the third spacer structure 18 is made of the same material as the source electrode 112 and the drain electrode 113 in the pixel circuit 11, and is formed by one composition process. The third spacer structure 18 is suspended and serves only to elevate the first conductive isolation pillar 31 and the second conductive isolation pillar 32.

In some embodiments, the third spacer structure 18 includes a single conductive layer or includes a plurality of stacked conductive layers.

In some embodiments, referring to FIG. 2c, FIG. 2p, and FIG. 2q, the conductive isolation pillar 3 includes a first conductive layer 33, a second conductive layer 34, and a third conductive layer 35, with the first conductive layer 33, the second conductive layer 34, and the third conductive layer 35 sequentially stacked away from the substrate 1. The edge surface of the second conductive layer 34 is a first slope, the edge surfaces of the first conductive layer 33 and the third conductive layer 35 are a second slope, and the slope angle of the first slope is smaller than the slope angle of the second slope. The orthographic projections of both the first conductive layer 33 and the third conductive layer 35 on the substrate 1 cover the orthographic projection of the second conductive layer 34 on the substrate 1.

The slope angle of the first slope surface ranges from 45°−10° to 45°+10°. The slope angle of the second slope surface is close to 90°.

In some embodiments, referring to FIG. 2s, the conductive isolation pillar 3 is formed from the same material as the conductive connection structure 116 in the pixel circuit 11 and by one composition process. The conductive isolation pillar 3 is suspended and serves only to isolate the organic material layer 5 from the first electrode 6 (i.e., the cathode).

In some embodiments, the first conductive layer 33 of the conductive isolation pillar 3 is made of titanium, the second conductive layer 34 is made of aluminum, and the third conductive layer 35 is made of titanium.

In some embodiments, referring to FIGS. 2b-2r, the insulative isolation layer 4 covers the surface of the side, away from the substrate 1, of the third conductive layer 35 and the edge end surfaces of the first conductive layer 33, the second conductive layer 34, and the third conductive layer 35, and the thickness of the insulative isolation layer 4 ranges from 500 to 2,000 Å. The insulative isolation layer 4 forms a wrap around the conductive isolation pillar 3, thereby blocking the conductive connection between the first electrode 6 and the conductive isolation pillar 3, such that the peripheral region 101 of the display panel in the reliability test does not become a charged electrode (i.e., with the voltage of the first electrode 6), and thereby avoiding the encapsulation failure of the encapsulation layer 9 at the border between the display region 100 and the peripheral region 101 and subsequently avoiding a display blackout at the border between the display region 100 and the peripheral region 101, thereby avoiding the phenomenon of GDSH at the border between the display region 100 and the peripheral region 101.

In some embodiments, the insulative isolation layer 4 is made of silicon nitride, silicon oxide, or silicon nitride oxide.

It should be noted that only the insulative isolation layer of the peripheral region and the graphics of each film layer below the conductive isolation pillar (i.e., to the substrate side) are shown in FIG. 2b, FIG. 2d, FIGS. 2f-2o, and FIG. 2r above, and none of the film layers (e.g., the organic material layer and the first electrode) above the insulative isolation layer are shown, but they are described in relevant text in the specification.

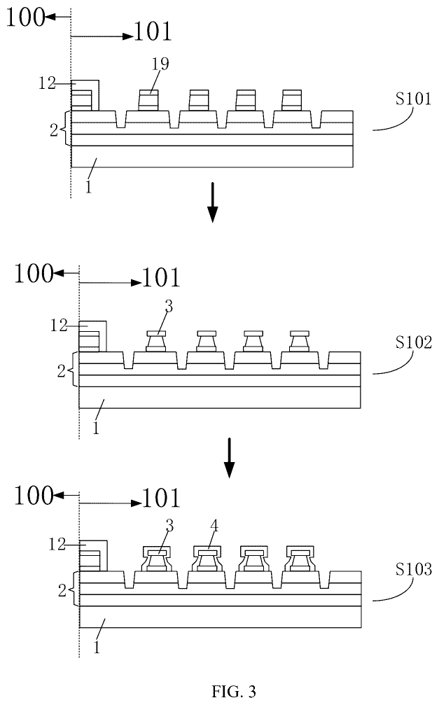

Embodiments of the present disclosure also provide a method for manufacturing the conductive isolation pillar and the insulative isolation layer, with reference to FIG. 3. FIG. 3 is a schematic diagram of the manufacturing process of the conductive isolation pillar and the insulative isolation layer in embodiments of the present disclosure. The method includes the following processes.

In S101, an inorganic insulating layer 2, a conductive film layer 19, and a planarization layer 12 are sequentially manufactured on the substrate 1.

In S102, a masking process is performed on the conductive film layer 19 in the peripheral region 101 to form a graphic of the conductive isolation pillar 3.

The composition process includes applying a photoresist, exposing and developing to remove the photoresist other than the graphic of the conductive isolation pillar, and then etching the graphic of the conductive isolation pillar 3 with an etching solution to form the graphic of the conductive isolation pillar 3, and ultimately forming the conductive isolation pillar 3 of the sandwich structure.

In S103, the graphic of the insulative isolation layer 4 is formed by a composition process.

The graphing process includes the steps of deposition, exposure, developing, and etching of the insulative isolation film layer. The specific processes are all relatively mature traditional techniques and are not repeated here.

In the display panel provide d by the embodiments of the present disclosure, by disposing the insulative isolation layer on the side, away from the substrate, of the conductive isolation pillar, and the orthographic projection of the insulative isolation layer on the substrate at least covering the orthographic projection of the conductive isolation pillar on the substrate, the insulative isolation layer is provided to elevate the height of the conductive isolation pillar, so as to contribute to isolating the organic material layer that extends from the display region to the peripheral region and the first electrode. Additionally, the insulative isolation layer blocks the conductive connection between the first electrode and the conductive isolation pillar, such that the peripheral region of the display panel in the reliability test does not become a charged electrode (i.e., with the voltage of the first electrode), and the reaction of the chemical substances within the polarizer in the display panel with the inorganic encapsulation layer in the encapsulation layer is avoided. That is, the inorganic encapsulation layer is prevented from being electrochemically reacted by electrochemical corrosion, and the failure of the encapsulation of the encapsulation layer at the border between the display region and the peripheral region is avoided, thereby avoiding the phenomenon of GDSH at the border between the display region and the peripheral region.

In a second aspect, embodiments of the present disclosure further provide a display device including a display panel in the above embodiment.

By using the display panel in the above embodiment, the display quality of the display device is improved.

The display device in the embodiments of the present disclosure is an OLED panel, an OLED TV, an OLED billboard, a monitor, a cell phone, a navigator, and any other product or component having a display function.

It is to be understood that the above embodiments are merely exemplary embodiments for the purpose of illustrating the principles of the present disclosure, but the present disclosure is not limited thereto. Various variations and improvements are made by a person of ordinary skill in the art without departing from the spirit and substance of the present disclosure, and such variations and improvements are also considered to be within the scope of protection of the present disclosure.

1. A display panel, having a display region, an aperture region, and a peripheral region, the peripheral region being disposed around the aperture region, and the display region surrounding the peripheral region;
wherein the display panel comprises:
a substrate, disposed within the display region and the peripheral region;
an inorganic insulating layer, disposed on a side of the substrate, and extending from the display region to the peripheral region;
a plurality of conductive isolation pillars, disposed on a side, away from the substrate, of the inorganic insulating layer and disposed within the peripheral region, wherein the plurality of conductive isolation pillars are sequentially arranged in a direction away from the display region;
an insulative isolation layer, disposed on a side, away from the substrate, of the conductive isolation pillars, and extending from the display region to the peripheral region, wherein an orthographic projection of the insulative isolation layer on the substrate at least covers an orthographic projection of each of the plurality of conductive isolation pillars on the substrate;
an organic material layer, disposed on a side, away from the substrate, of the insulative isolation layer and extending from the display region to the peripheral region, wherein the organic material layer is disconnected at the conductive isolation pillar; and
a first electrode, disposed on a side, away from the substrate, of the organic material layer and extending from the display region to the peripheral region, wherein the first electrode is disconnected at the conductive isolation pillar.

2. The display panel according to claim 1, further comprising an enclosure dam, disposed within the peripheral region and disposed between the inorganic insulating layer and the insulative isolation layer, and the enclosure dam surrounding the aperture region; wherein
the plurality of conductive isolation pillars comprise a plurality of first conductive isolation pillars and a plurality of second conductive isolation pillars; wherein
the plurality of first conductive isolation pillars are disposed on a side, close to the display region, of the enclosure dam, and the plurality of first conductive isolation pillars are spaced sequentially in a direction away from the display region;
the plurality of second conductive isolation pillars are disposed on a side, away from the display region, of the enclosure dam, and the plurality of second conductive isolation pillars are spaced sequentially in a direction away from the display region; and
the orthographic projection of the insulative isolation layer on the substrate is at least partially not overlapped with an orthographic projection of the enclosure dam on the substrate.

3. The display panel according to claim 2, wherein a plurality of first grooves are disposed in the inorganic insulating layer; wherein
the plurality of first grooves are disposed in a region between the enclosure dam and the display region; and
the plurality of first grooves are sequentially arranged in a direction away from the display region, and an orthographic projection of each of the plurality of first grooves on the substrate is not overlapped with an orthographic projection of each of the plurality of first conductive isolation pillars on the substrate.

4. The display panel according to claim 2, wherein a first groove is disposed in the inorganic insulating layer; wherein
the first groove is disposed in a region between the enclosure dam and the display region; and
an orthographic projection of each of the plurality of first conductive isolation pillars on the substrate is within an orthographic projection of the first groove on the substrate.

5. The display panel according to claim 4, wherein a second groove is further disposed in the inorganic insulating layer; wherein
the second groove are disposed in a region between the enclosure dam and the aperture region; and
an orthographic projection of each of the plurality of second conductive isolation pillars on the substrate is within an orthographic projection of the second groove on the substrate.

6. The display panel according to claim 5, wherein the orthographic projection of the insulative isolation layer on the substrate is overlapped with the orthographic projection of the first groove and the orthographic projection of the second groove on the substrate.

7. The display panel according to claim 1, further comprising an isolation structure disposed between the inorganic insulating layer and the insulative isolation layer, and disposed within a non-display region of the peripheral region bordering the display region; wherein
the isolation structure comprises a conductive portion and a planarization layer, wherein the conductive portion and the conductive isolation pillar are made of a same material and are disposed in a same layer, the planarization layer is disposed on a side, away from the substrate, of the conductive portion, and an orthographic projection of the planarization layer on the substrate covers an orthographic projection of the conductive portion on the substrate;
wherein
the orthographic projection of the planarization layer on the substrate is not overlapped with the conductive isolation pillar;
an isolation groove is disposed on a side, away from the substrate, of the planarization layer, and the orthographic projection of the insulative isolation layer on the substrate covers the orthographic projection of the planarization layer other than the isolation groove in the non-display region on the substrate, wherein a cross-sectional shape of the isolation groove perpendicular to the substrate comprises a trapezoidal shape; and
the organic material layer or the organic material layer and the first electrode are disconnected at the isolation groove.

8. The display panel according to claim 2, wherein
the inorganic insulating layer comprises a plurality of sub-layers, the plurality of sub-layers being sequentially stacked; and
the display panel further comprises a plurality of first spacer structures disposed in the peripheral region and disposed between adjacent sub-layers;
wherein the plurality of first spacer structures are in one-to-one correspondence with the plurality of second conductive isolation pillars, and an orthographic projection of each of the plurality of first spacer structures on the substrate is overlapped with an orthographic projection of each of the plurality of second conductive isolation pillars on the substrate.

9. The display panel according to claim 8, further comprising a plurality of second spacer structures disposed in the peripheral region and disposed between adjacent sub-layers;
wherein the plurality of second spacer structures are in one-to-one correspondence with the plurality of first conductive isolation pillars, and each of the plurality of second spacer structures is overlapped with an orthographic projection of each of the plurality of first conductive isolation pillars on the substrate.

10. The display panel according to claim 9, wherein
the inorganic insulating layer comprises a first sub-layer and a second sub-layer, the first sub-layer and the second sub-layer being sequentially stacked away from the substrate; and
the first spacer structure comprises a first conductive pattern, and the second spacer structure comprises a second conductive pattern;
wherein
the first conductive pattern and the second conductive pattern are made of a same material and are disposed in a same layer; and
the first conductive pattern and the second conductive pattern are disposed between the first sub-layer and the second sub-layer.

11. The display panel according to claim 10, wherein
the inorganic insulating layer further comprises a third sub-layer disposed on a side, away from the substrate, of the second sub-layer back; and
the first spacer structure further comprises a third conductive pattern, and the second spacer structure further comprises a fourth conductive pattern;
wherein
the third conductive pattern and the fourth conductive pattern are made of a same material and are disposed in a same layer; and
the third conductive pattern and the fourth conductive pattern are disposed between the second sub-layer and the third sub-layer.

12. The display panel according to claim 11, wherein
centers of orthographic projections of the second conductive isolation pillar, the third conductive pattern, and the first conductive pattern on the substrate are coincident with each other;
any one side edge of the orthographic projection of the third conductive pattern on the substrate is retracted inwardly by 0.5 to 1 μm toward the center of the orthographic projection of the third conductive pattern relative to a corresponding side edge of the orthographic projection of the first conductive pattern on the substrate; and
any one side edge of the orthographic projection of the second conductive isolation pillar on the substrate is retracted inwardly by 0.5 to 1 μm toward the center of the orthographic projection of the second conductive isolation pillar relative to a corresponding side edge of the orthographic projection of third conductive pattern on the substrate.

13. The display panel according to claim 11, wherein
centers of orthographic projections of the first conductive isolation pillar, the fourth conductive pattern, and the second conductive pattern on the substrate are coincident with each other;
any one side edge of the orthographic projection of the fourth conductive pattern on the substrate is retracted inwardly by 0.5 to 1 μm toward the center of the orthographic projection of the fourth conductive pattern relative to a corresponding side edge of the orthographic projection of the second conductive pattern on the substrate; and
any one side edge of the orthographic projection of the first conductive isolation pillar on the substrate is retracted inwardly by 0.5 to 1 μm toward the center of the orthographic projection of the first conductive isolation pillar relative to a corresponding side edge of the orthographic projection of the fourth conductive pattern on the substrate.

14. The display panel according to claim 11, wherein edge surfaces of the first conductive pattern, the second conductive pattern, the third conductive pattern, and the fourth conductive pattern are sloped surfaces;
wherein a slope angle of the sloped surface is 45°+10°.

15. The display panel according to claim 2, further comprising a plurality of third spacer structures disposed within the peripheral region and between the inorganic insulating layer and the conductive isolation pillar; wherein
the plurality of third spacer structures are in one-to-one correspondence with the plurality of first conductive isolation pillars and the plurality of second conductive isolation pillars, each of the plurality of third spacer structures is overlapped with an orthographic projection of each of the plurality of first conductive isolation pillars on the substrate, and each of the plurality of third spacer structures is overlapped with an orthographic projection of each of the plurality of second conductive isolation pillars on the substrate; and
the orthographic projection of the insulative isolation layer on the substrate is overlapped with an orthographic projection of each of the plurality of third spacer structures on the substrate.

16. The display panel according to claim 15, wherein a cross-sectional shape of the third spacer structure perpendicular to the substrate comprises a trapezoidal shape;
wherein a bottom angle of the trapezoidal shape is 45°+10°.

17. The display panel according to claim 16, wherein
each of the plurality of first conductive isolation pillars is coincident with a center of the orthographic projection of each of the plurality of third spacer structures on the substrate;
each of the plurality of second conductive isolation pillars is coincident with the center of the orthographic projection of each of the plurality of third spacer structures on the substrate;
any one side edge of the orthographic projection of each of the plurality of first conductive isolation pillars on the substrate is retracted inwardly by 0.5 to 1 μm toward the center of the orthographic projection of each of the plurality of first conductive isolation pillars relative to a corresponding side edge of an orthographic projection of a top surface of the third spacer structure contacted with the first conductive isolation pillar on the substrate; and
any one side edge of the orthographic projection of each of the plurality of second conductive isolation pillars on the substrate is retracted inwardly by 0.5 to 1 μm toward a center of the orthographic projection of each of the plurality of second conductive isolation pillars relative to a corresponding side edge of an orthographic projection of a top surface of the third spacer structure contacted with the second conductive isolation pillar on the substrate.

18. The display panel according to claim 1, wherein each of the plurality of conductive isolation pillar comprises a first conductive layer, a second conductive layer, and a third conductive layer, the first conductive layer, the second conductive layer, and the third conductive layer being stacked sequentially away from the substrate; wherein
an edge surface of the second conductive layer is a first slope surface, and edge surfaces of the first conductive layer and the third conductive layer are second slope surfaces;
a slope angle of the first slope surface is less than a slope angle of the second slope surface; and
orthographic projections of the first conductive layer and the third conductive layer on the substrate both cover an orthographic projection of the second conductive layer on the substrate.

19. The display panel according to claim 18, wherein the insulative isolation layer covers a side surface, away from the substrate, of the third conductive layer and the edge surfaces of the first conductive layer, the second conductive layer and the third conductive layer; and
a thickness of the insulative isolation layer ranges from 500 Å to 2000 Å.

20. A display device, comprising a display panel, wherein the display panel has a display region, an aperture region, and a peripheral region, the peripheral region being disposed around the aperture region, and the display region surrounding the peripheral region;
wherein the display panel comprises:
a substrate, disposed within the display region and the peripheral region;
an inorganic insulating layer, disposed on a side of the substrate, and extending from the display region to the peripheral region;
a plurality of conductive isolation pillars, disposed on a side, away from the substrate, of the inorganic insulating layer and disposed within the peripheral region, wherein the plurality of conductive isolation pillars are sequentially arranged in a direction away from the display region;
an insulative isolation layer, disposed on a side, away from the substrate, of the conductive isolation pillars, and extending from the display region to the peripheral region, wherein an orthographic projection of the insulative isolation layer on the substrate at least covers an orthographic projection of each of the plurality of conductive isolation pillars on the substrate;
an organic material layer, disposed on a side, away from the substrate, of the insulative isolation layer and extending from the display region to the peripheral region, wherein the organic material layer is disconnected at the conductive isolation pillar; and
a first electrode, disposed on a side, away from the substrate, of the organic material layer and extending from the display region to the peripheral region, wherein the first electrode is disconnected at the conductive isolation pillar.
